(19) United States
(12) Patent Application Publication
(10) Pub. No.: US 2026/0103914 A1
(43) Pub. Date: Apr. 16, 2026

(54) Electronic Tombstone Device

(71) Applicants: Trever Papavasiliou, Culpeper, VA (US); Nick Papavasiliou, Lowell, MA (US)

(72) Inventors: Trever Papavasiliou, Culpeper, VA (US); Nick Papavasiliou, Lowell, MA (US)

(21) Appl. No.: 19/040,368

(22) Filed: Jan. 29, 2025

Related U.S. Application Data
(60) Provisional application No. 63/705,602, filed on Oct. 10, 2024.

(51) Int. Cl. E04H 13/00; A01M 29/18; G06K 19/06; G09G 3/32; H02S 20/20; H10H 29/855

(52) U.S. Cl. CPC E04H 13/003; A01M 29/18; G06K 19/06037; G09G 3/32; H10H 29/855; G09G 2320/0626; G09G 2354/00; G09G 2360/144; H02S 20/20

(57) ABSTRACT

An electronic tombstone device is provided. The device is comprised of a multifunctional tombstone device designed to enhance personalization, interactivity, and durability for outdoor applications. The device comprises a body featuring an LED display with anti-glare, scratch-resistant, and oleophobic treatments to support media playback in diverse orientations. Integrated lighting provides aesthetic and functional illumination, including customizable modes such as motion-activated or candlelight effects. The device also incorporates weatherproof speakers for personalized audio playback and motion sensors for triggering interactive features like media displays and lighting. Media uploads are facilitated via a secure, weather-resistant QR code leading to a password-protected webpage. Power options include solar panels with energy storage or alternative wired solutions. Additional features include motion-activated animal deterrents, protected storage compartments for tributes, and integrated vases with drainage systems, ensuring functionality and respect for memorial environments.

### CROSS-REFERENCE TO RELATED APPLICATION

The present application claims priority to, and the benefit of, U.S. Provisional Application No. 63/705,602, which was filed on Oct. 10, 2024, and is incorporated herein by reference in its entirety.

### FIELD OF THE INVENTION

The present invention relates generally to the field of tombstones. More specifically, the present invention relates to a tombstone comprising a body with integrated LED displays, lighting, weatherproof speakers, and motion sensors for interactive media playback and illumination. Additional features include secure media uploads via a weather-resistant QR code, solar or wired power options, and additional elements like animal deterrents, tribute storage compartments, and integrated vases for enhanced personalization and functionality in outdoor environments. Accordingly, the present disclosure makes specific reference thereto. Nonetheless, it is to be appreciated that aspects of the present invention are also equally applicable to other like applications, devices, and methods of manufacture.

### BACKGROUND

Traditional tombstones, while serving as enduring markers of remembrance, offer limited functionality and flexibility in memorializing loved ones. Families and friends often attempt to personalize gravesites with flowers, photographs, and small decorations to honor the deceased. However, these efforts are frequently hindered by environmental factors such as rain, wind, and extreme temperatures, which can damage or destroy these tributes. Wildlife can further exacerbate the problem by disturbing or displacing decorations. Additionally, theft or vandalism poses a constant risk to any items left at the site. This creates an ongoing challenge for families who wish to maintain the gravesite's appearance and ensure the longevity of their tributes.

Another significant limitation of traditional tombstones is their inability to provide illumination. During low light hours or nighttime visits, visitors may struggle to locate or view their loved one's gravesite, particularly in larger cemeteries. This lack of visibility can hinder individuals from fully experiencing moments of reflection or connection. Furthermore, conventional tombstones are static and cannot evolve to reflect the changing lives and memories of the deceased's family and friends. While many people cherish the idea of sharing new photos, messages, or videos over time, current solutions do not offer a way to integrate these updates into the gravesite. As digital technology becomes an increasingly integral part of daily life, there is growing interest in creating memorials that incorporate dynamic, interactive elements to better commemorate loved ones. These shortcomings underscore the need for an innovative solution that combines modern technology with traditional gravestone functionality to create a more meaningful, durable, and customizable memorial experience.

Therefore, there exists a long-felt need in the art for electronic tombstone devices that provide a secure and weather-resistant tombstone for memorializing loved ones. There also exists a long-felt need in the art for electronic tombstone devices that offer illumination to enhance visibility during lowlight hours. Moreover, there exists a long-felt need in the art for electronic tombstone devices that enable families to upload and update digital tributes such as photos, videos, and messages remotely.

The subject matter disclosed and claimed herein, in one embodiment thereof, comprises an electronic tombstone device. The device is comprised of a multifunctional tombstone device designed to enhance personalization, interactivity, and durability for outdoor applications. The device comprises a body featuring an LED display with anti-glare, scratch-resistant, and oleophobic treatments to support media playback in diverse orientations. Integrated lighting provides aesthetic and functional illumination, including customizable modes such as motion-activated or candlelight effects. The device also incorporates weatherproof speakers for personalized audio playback and motion sensors for triggering interactive features like media displays and lighting. Media uploads are facilitated via a secure, weather-resistant QR code leading to a password-protected webpage. Power options include solar panels with energy storage or alternative wired solutions. Additional features include motion-activated animal deterrents, protected storage compartments for tributes, and integrated vases with drainage systems, ensuring functionality and respect for memorial environments.

In this manner, the electronic tombstone device of the present invention accomplishes all the foregoing objectives and provides a tombstone with an integrated LED screen capable of displaying photos, videos, and other digital media. The device enhances gravesite visibility with built-in lighting, ensuring it can be seen in lowlight conditions. The device also allows families and friends to update the displayed media by scanning a QR code linked to a mobile application, facilitating ongoing personalization. The device is powered by solar energy or rechargeable batteries, ensuring continuous functionality while being environmentally sustainable. By protecting decorations from weather, animals, and theft, and offering an innovative, interactive way to memorialize loved ones, the electronic tombstone device provides a modern and durable solution to traditional gravesite challenges.

### SUMMARY

The following presents a simplified summary to provide a basic understanding of some aspects of the disclosed innovation. This summary is not an extensive overview, and it is not intended to identify key/critical elements or to delineate the scope thereof. Its sole purpose is to present some general concepts in a simplified form as a prelude to the more detailed description that is presented later.

The subject matter disclosed and claimed herein, in one embodiment thereof, comprises an electronic tombstone device comprised of a tombstone-shaped body, made of materials such as marble, granite, treated steel, or composites, and is customizable in shape and theme.

The body is comprised of at least one LED screen display featuring anti-glare coatings, automatic brightness sensors for optimal visibility, and durable, anti-scratch tempered glass with oleophobic treatments. The display supports media playback in multiple formats and orientations, with optional touch-sensitive and voice-command functionalities for interactive content navigation.

The device is comprised of integrated lighting components, such as LED strips or spotlights, offering multiple modes, including continuous illumination, scheduled activation, and motion-triggered effects. A “memorial mode” mimics candlelight for a serene ambiance, and repositionable mounts enable adjustable placement.

The device is further comprised of weatherproof speakers for audio playback, with motion sensors enabling interactive features such as activating the display, lights, and audio upon detecting a visitor's presence. Media uploads are facilitated via a durable, weather-resistant QR code linking to a secure webpage with password protection and multi-factor authentication for privacy.

Power is supplied by solar panels mounted for optimal sunlight exposure, with energy stored in batteries for night or overcast conditions. Alternative wired or rechargeable battery options are also available in different embodiments.

The body is comprised of additional features, including motion-activated ultrasonic devices to deter animals, storage compartments for small tributes, and integrated vases to maintain floral arrangements. These elements collectively enhance the device's usability, personalization, and durability in outdoor environments.

Accordingly, the electronic tombstone device of the present invention is particularly advantageous as it provides a tombstone with an integrated LED screen capable of displaying photos, videos, and other digital media. The device enhances gravesite visibility with built-in lighting, ensuring it can be seen in lowlight conditions. The device also allows families and friends to update the displayed media by scanning a QR code linked to a mobile application, facilitating ongoing personalization. The device is powered by solar energy or rechargeable batteries, ensuring continuous functionality while being environmentally sustainable. By protecting decorations from weather, animals, and theft, and offering an innovative, interactive way to memorialize loved ones, the electronic tombstone device provides a modern and durable solution to traditional gravesite challenges. In this manner, the electronic tombstone device overcomes the limitations of existing tombstones known in the art.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and are intended to include all such aspects and their equivalents. Other advantages and novel features will become apparent from the following detailed description when considered in conjunction with the drawings.

### BRIEF DESCRIPTION OF THE DRAWINGS

The description refers to provided drawings in which similar reference characters refer to similar parts throughout the different views, and in which:

FIG. 1 illustrates a perspective view of one potential embodiment of an electronic tombstone device of the present invention in accordance with the disclosed architecture; and

FIG. 2 illustrates a graphical view of a website/mobile application of one potential embodiment of an electronic tombstone device of the present invention in accordance with the disclosed architecture.

### DETAILED DESCRIPTION

The innovation is now described with reference to the drawings, wherein like reference numerals are used to refer to like elements throughout. In the following description, for purposes of explanation, numerous specific details are set forth to provide a thorough understanding thereof. It may be evident, however, that the innovation can be practiced without these specific details. In other instances, well-known structures and devices are shown in block diagram form to facilitate a description thereof. Various embodiments are discussed hereinafter. It should be noted that the figures are described only to facilitate the description of the embodiments. They are not intended as an exhaustive description of the invention and do not limit the scope of the invention. Additionally, an illustrated embodiment need not have all the aspects or advantages shown. Thus, in other embodiments, any of the features described herein from different embodiments may be combined.

As noted above, there exists a long-felt need in the art for electronic tombstone devices that provide a secure and weather-resistant tombstone for memorializing loved ones. There also exists a long-felt need in the art for electronic tombstone devices that offer illumination to enhance visibility during lowlight hours. Moreover, there exists a long-felt need in the art for electronic tombstone devices that enable families to upload and update digital tributes such as photos, videos, and messages remotely.

The present invention, in one exemplary embodiment, is comprised of an electronic tombstone device comprised of a tombstone-shaped body, constructed from materials such as marble, granite, treated steel, or composites, and customizable in both shape and theme.

The body is comprised of at least one LED screen display with anti-glare coatings, automatic brightness sensors for improved visibility, and durable, anti-scratch tempered glass treated with oleophobic coatings. The display supports media playback in various formats and orientations, with optional touch-sensitive and voice-command functionalities to enable interactive content navigation.

The device is comprised of integrated lighting components, such as LED strips or spotlights, which provide multiple modes, including continuous illumination, scheduled activation, and motion-triggered effects. A “memorial mode” produces a candlelight-like flickering effect, and repositionable mounts allow adjustable placement of the lighting components.

The device is further comprised of weatherproof speakers for audio playback, with motion sensors that enable features such as activating the display, lights, and audio when a visitor is detected. Media uploads are supported via a durable, weather-resistant QR code that links to a secure webpage with password protection and multi-factor authentication for privacy.

Power is supplied through solar panels mounted for optimal sunlight exposure, with energy stored in batteries for use during nighttime or overcast conditions. Alternative wired or rechargeable battery options are available in different embodiments.

The body is comprised of additional features, including motion-activated ultrasonic devices to deter animals, storage compartments for small tributes, and integrated vases with drainage systems to preserve floral arrangements. These features enhance usability, personalization, and durability in outdoor settings.

The electronic tombstone device provides a modern solution by integrating an LED screen for displaying photos, videos, and digital media, along with built-in lighting for enhanced gravesite visibility. The QR code functionality allows ongoing personalization, and the use of solar energy or rechargeable batteries ensures environmentally sustainable operation. By protecting decorations from weather, animals, and theft, the device addresses challenges faced by traditional tombstones and offers an interactive and durable way to memorialize loved ones, overcoming the limitations of existing designs.

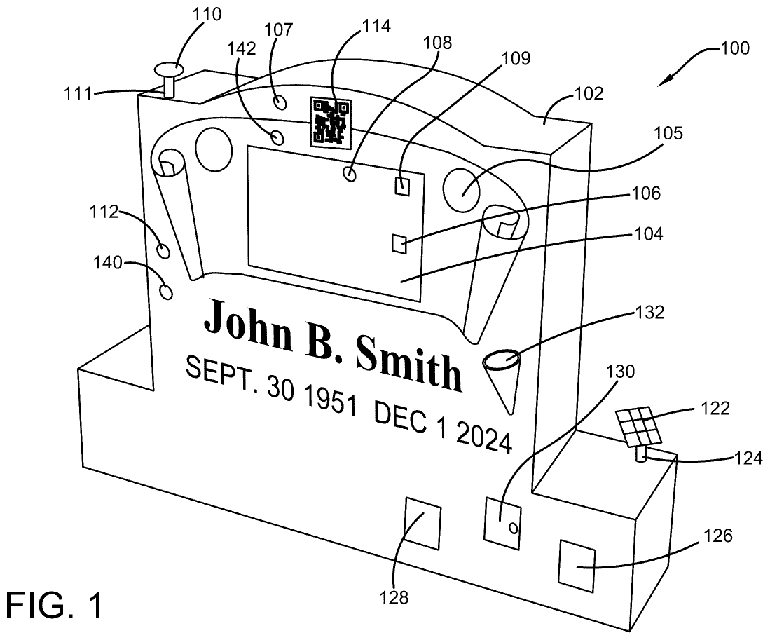

Referring initially to the drawings, FIG. 1 illustrates a perspective view of one potential embodiment of an electronic tombstone device 100 of the present invention in accordance with the disclosed architecture. The device 100 is comprised of several key features designed to enhance functionality, durability, and user experience. More specifically, the device 100 is comprised of a body 102. The body 102 may be any tombstone shape, such as, but not limited to, rectangular, curved, or custom artistic forms designed to reflect individual preferences or themes. The body 102 may be made from any material, such as, but not limited to, marble, granite, treated steel, or composite materials engineered for durability in outdoor conditions.

The body 102 is comprised of at least one LED screen display 104, as seen in FIG. 1. The display 104 may be comprised of an anti-glare coating 106 to enhance visibility under various lighting conditions, including direct sunlight or overcast skies. Additionally, an automatic brightness sensor 108 is integrated to adapt the brightness of the display 104 dynamically, ensuring optimal visibility during transitions from day to night or in dim environments. To ensure durability and maintain long-term functionality, the display 104 is comprised of an anti-scratch tempered glass, which may be further treated with oleophobic coatings 109 to resist fingerprints and smudges, thus reducing maintenance requirements. The display 104 is capable of enabling playback of various media file types, such as JPEG, PNG, and MP4, and supports both landscape and portrait orientations for content presentation. Optionally, the display 104 may include touch-sensitive functionality, which allows users to interact directly with the display 104 by swiping through photo galleries, selecting specific videos, or zooming into images for a closer view. In one embodiment, the display 104 may be controlled via voice commands, providing an additional layer of accessibility for users.

The body 102 is further comprised of at least one light 110, as seen in FIG. 1. The light 110 may be any type of lighting component, such as, but not limited to, LED strips or spotlights, which are integrated into the body 102 to provide illumination that enhances the monument's design. The light 110 is capable of operating in a plurality of lighting modes, including continuous illumination for a steady glow, timed schedules for specific activation periods, and motion-triggered activation as detected by at least one motion sensor 112. In one embodiment, the light 110 may include a specialized “memorial mode,” which provides flickering effects designed to mimic the appearance of candlelight, creating a serene and respectful ambiance during memorial visits. In one embodiment, the lights 110 are attached via at least one adjustable/repositionable mount 111.

The device 100 may also be comprised of at least one weatherproof speaker 105, which is capable of playing recorded messages, favorite songs, or curated playlists to personalize the memorial experience. In one embodiment, at least one motion sensor 107 is included to activate certain features of the device 100. For example, when visitors approach the device 100, the motion sensor 107 may trigger the activation of the display 104, the lights 110, audio playback from the speaker 105, specific slideshows on the display 104, etc., thereby creating an interactive and responsive experience.

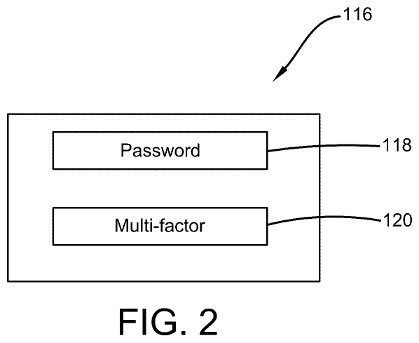

Media upload functionality to the display 104 is facilitated through a laser-etched QR code 114 that is integrated into the body 102. The QR code 114 is designed to be durable and weather-resistant, allowing it to remain functional under outdoor conditions such as exposure to rain, sunlight, or temperature fluctuations. Preferably, the QR code 114 is positioned discreetly on the body 102, such as on the base or edge, where it remains accessible but does not detract from the aesthetic design. When scanned, the QR code 114 directs users to a secure webpage/mobile application 116 where photos, videos, and messages can be uploaded for display on the LED screen 104. The webpage/application 116 is preferably secured through password protection 118 or multi-factor authentication 120, as seen in FIG. 2, to prevent unauthorized access or uploads, thereby maintaining the privacy and integrity of the content. In a different embodiment, the device 100 is comprised of a Bluetooth transmitter 140 that allows a user to wirelessly connect a smart device to the device 100 in order to upload content to the screen 104. In addition, the screen 104 may also be comprised of a hologram projector 142 that can project 3D holograms as uploaded via a smart device and/or the QR code 114.

The display 104 is powered by at least one solar panel 122 in one embodiment. The solar panel 122 may be attached to the body 102 via at least one adjustable mount 124, such as, but not limited to, pivoting brackets or fixed angled mounts, which allow the solar panel 122 to optimize its positioning for maximum sunlight exposure. Power generated by the solar panel 122 is stored in at least one battery 126, which is capable of retaining excess energy generated during the day for use at night or during overcast weather. In areas where solar power is impractical, the device 100 may alternatively be powered by a wired battery 126 or a rechargeable battery 126, providing flexible options to accommodate various environmental and logistical requirements.

The device 100 further incorporates comprehensive measures to protect decorations and media. To deter animals, the device 100 may include motion-activated ultrasonic devices 128, such as, but not limited to, emitters or speakers, which are calibrated to specific frequencies that gently discourage animal interference without disturbing visitors or detracting from the solemn environment. In one embodiment, the body 102 is comprised of storage compartments 130 for storing small tributes, such as flowers or keepsakes, in a protected environment. Additionally, the body 102 may be comprised of integrated vases 132, which are designed to hold floral arrangements.

Certain terms are used throughout the following description and claims to refer to particular features or components. As one skilled in the art will appreciate, different persons may refer to the same feature or component by different names. This document does not intend to distinguish between components or features that differ in name but not structure or function. As used herein “electronic tombstone device” and “device” are interchangeable and refer to the electronic tombstone device 100 of the present invention.

Notwithstanding the foregoing, the electronic tombstone device 100 of the present invention and its various components can be of any suitable size and configuration as is known in the art without affecting the overall concept of the invention, provided that they accomplish the above-stated objectives. One of ordinary skill in the art will appreciate that the size, configuration, and material of the electronic tombstone device 100 as shown in the FIGS. are for illustrative purposes only, and that many other sizes and shapes of the electronic tombstone device 100 are well within the scope of the present disclosure. Although the dimensions of the electronic tombstone device 100 are important design parameters for user convenience, the electronic tombstone device 100 may be of any size, shape, and/or configuration that ensures optimal performance during use and/or that suits the user's needs and/or preferences.

Various modifications and additions can be made to the exemplary embodiments discussed without departing from the scope of the present invention. While the embodiments described above refer to particular features, the scope of this invention also includes embodiments having different combinations of features and embodiments that do not include all the described features. Accordingly, the scope of the present invention is intended to embrace all such alternatives, modifications, and variations as fall within the scope of the claims, together with all equivalents thereof.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications, and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. An electronic tombstone device comprising:
a body, wherein the body is tombstone-shaped;
an LED screen display integrated into the body, wherein the LED screen display comprises:
an anti-glare coating,
an automatic brightness sensor configured to dynamically adjust a brightness of the LED screen display, and
an anti-scratch tempered glass comprised of an oleophobic coating;
a laser-etched QR code integrated into the body, wherein the QR code directs users to a webpage or a mobile application configured to facilitate the upload of a media for display on the LED screen display; and
a light integrated into the body.

2. The electronic tombstone device of claim 1, wherein the light is configured to operate in a continuous illumination mode, a timed schedule mode, and a motion-triggered activation mode.

3. The electronic tombstone device of claim 1, wherein the LED screen display is comprised of a touchscreen.

4. The electronic tombstone device of claim 1, wherein the LED screen display is configured to be controlled by a voice command.

5. The electronic tombstone device of claim 1, wherein the light attaches to the body via an adjustable mount.

6. The electronic tombstone device of claim 1 further comprised of a motion sensor configured to activate the LED screen display and the light.

7. The electronic tombstone device of claim 1 further comprised of a weatherproof speaker.

8. An electronic tombstone device comprising:
a body, wherein the body is tombstone-shaped;
an LED screen display integrated into the body, wherein the LED screen display comprises:
an anti-glare coating,
an automatic brightness sensor configured to dynamically adjust a brightness of the LED screen display, and
an anti-scratch tempered glass comprised of an oleophobic coating;
a laser-etched QR code integrated into the body, wherein the QR code directs users to a webpage or a mobile application configured to facilitate the upload of a media for display on the LED screen display;
a solar panel;
a speaker; and
a light integrated into the body.

9. The electronic tombstone device of claim 8, wherein the mobile application is comprised of multi-factor identification.

10. The electronic tombstone device of claim 8, wherein the webpage is comprised of multi-factor identification.

11. The electronic tombstone device of claim 8, wherein the solar panel powers the LED screen display.

12. The electronic tombstone device of claim 8, wherein the solar panel attaches to the body via an adjustable mount.

13. The electronic tombstone device of claim 8 further comprised of a motion-activated ultrasonic device.

14. The electronic tombstone device of claim 8 further comprised of a battery.

15. An electronic tombstone device comprising:
a body, wherein the body is tombstone-shaped and comprised of an integrated vase;
an LED screen display integrated into the body, wherein the LED screen display comprises:
an anti-glare coating,
an automatic brightness sensor configured to dynamically adjust a brightness of the LED screen display, and
an anti-scratch tempered glass comprised of an oleophobic coating;
a laser-etched QR code integrated into the body, wherein the QR code directs users to a webpage or a mobile application configured to facilitate the upload of a media for display on the LED screen display;
a solar panel;
a speaker; and
a light integrated into the body.

16. The electronic tombstone device of claim 15 further comprised of a storage compartment.

17. The electronic tombstone device of claim 15 further comprised of a motion-activated ultrasonic device integrated into the body, wherein the ultrasonic device deters animals.

18. The electronic tombstone device of claim 15 further comprised of a rechargeable battery.

19. The electronic tombstone device of claim 15, wherein the speaker is comprised of a weatherproof speaker.

20. The electronic tombstone device of claim 15, wherein the solar panel attaches to the body via an adjustable mount.
